(19) United States
(12) Patent Application Publication
(10) Pub. No.: US 2011/0068659 A1
(43) Pub. Date: Mar. 24, 2011

(54) PIEZOELECTRIC VIBRATING DEVICES AND METHODS FOR MANUFACTURING SAME

(75) Inventor: Ryoichi Ichikawa, Saitama (JP)

(73) Assignee: Nihon Dempa Kogyo Co., LTD.

(21) Appl. No.: 12/888,656

(22) Filed: Sep. 23, 2010

(30) Foreign Application Priority Data
Sep. 24, 2009 (JP) JP 2009-218703
Mar. 25, 2010 (JP) JP 2010-069444

(51) Int. Cl. H01L 41/053; H01L 41/22

(52) U.S. Cl. 310/344; 29/25.35

(57) ABSTRACT

Methods are disclosed for manufacturing piezoelectric vibrating devices. An exemplary method includes preparing a base wafer defining multiple bases each including stripes of a first bonding film extending along respective edges of the bases and first indents adjacent to and contacting respective stripes of the first bonding film. Also prepared is a lid wafer defining multiple lids each including stripes of a second bonding film extending along respective edges of the lids and second indents adjacent to and contacting respective stripes of the second bonding film. A unit of bonding material (e.g., a bonding “ball”) is applied to each of the first indents or to each of the second indents. Bonding together the base wafer and lid wafer is completed by melting the bonding material to flow the bonding material along the stripes, followed by solidifying the bonding material.

### CROSS-REFERENCE TO RELATED APPLICATION

This application claims priority to and the benefit of Japan Patent Application No. 2009-218703, filed on Sep. 24, 2009, and Japan Patent Application No. 2010-069444 filed on Mar. 25, 2010, in the Japan Patent Office, the disclosures of which are incorporated herein by reference in their respective entireties.

### FIELD

The present invention relates to, inter alia, piezoelectric devices and to methods for manufacturing such devices at mass-production levels.

### DESCRIPTION OF THE RELATED ART

With the progress of miniaturization and/or increases in the operating frequency of mobile communication apparatus and office automation (OA) equipment, piezoelectric devices used in this equipment must be made progressively smaller. For reducing manufacturing costs, the methods for manufacturing these devices must be optimized as much as possible.

According to the method for manufacturing piezoelectric device disclosed in Japan Unexamined Patent Application No. 2008-182468, individual lids are placed on and attached to respective “packages,” on a “package wafer” including multiple packages, wherein each package comprises a respective piezoelectric vibrating piece. The lids are fitted to the packages with the aid of “guide parts,” followed by hermetic bonding of the lids to the packages. Then the package wafer is cut device-by-device to separate the multiple individual piezoelectric devices from each other. This method is effective for preventing misalignments of lids with their respective packages and can be used for mass-production. However, the method disclosed in the '468 reference must be performed device-by-device on the package wafer. Each lid is manufactured individually and individually attached to a respective package on the wafer. This device-by-device assembly is inefficient, perhaps too inefficient for modern mass-production.

An object of the invention is to provide piezoelectric vibrating devices exhibiting long-term stability and to provide efficient methods for their manufacture.

### SUMMARY

According to a first aspect of the invention, methods are provided for manufacturing piezoelectric devices. An embodiment of such a method comprises preparing a base wafer defining multiple bases and preparing a lid wafer defining multiple lids. Each base has respective sides and a respective periphery, and includes a respective stripe of a first bonding film extending inboard of each edge around the periphery. Each base also includes at least one first indent formed adjacent each respective edge and contacting the respective stripe of the first bonding film. Each lid has respective sides and a respective periphery, and includes a respective stripe of a second bonding film extending inboard of each edge around the periphery. Each lid also includes at least one second indent formed adjacent each respective edge and contacting the respective stripe of the second bonding film. The stripes of bonding film and indents on the lid wafer are aligned with corresponding stripes and indents on the base wafer. A respective unit of bonding material is applied onto each of the first indents or each of the second indents. The lid wafer is aligned with the base wafer such that the wafers are separated from each other by the units of bonding material situated between respective opposing first and second indents. The units of bonding material are melted to produce flow of the molten bonding material from the indents along the stripes of the first and second bonding films. The bonding material is then solidified to bond the base wafer and lid wafer together to form a package wafer.

The package wafer is cut between adjacent stripes to release individual piezoelectric devices from the package wafer and to separate them from each other. This method provides mass-production of piezoelectric devices exhibiting long-term high stability.

Each of the first and second indents has a hemispherical shape, for example. The intents can be formed by etching using a mask having respective holes that define the shape and locations of the indents. Bonding together the lid wafer and base wafer can be performed under a vacuum state or in an inert gas environment.

The manufacturing method can further comprise, after forming the package wafer, cutting (“dicing”) the package wafer between adjacent stripes to separate the piezoelectric devices from the package wafer and from each other. The stripes of the first and second bonding films desirably are formed at respective regions in which the stripes thereof are not cut in the cutting step.

Preparing the base wafer desirably includes providing the base wafer with cutting grooves that are used in the cutting step. A respective cutting groove is located between flanking stripes of respective adjacent piezoelectric vibrating devices, so the cutting grooves collectively define the outline profiles of the piezoelectric vibrating devices in the package wafer. Similarly, preparing a lid wafer includes providing the lid wafer with cutting grooves that are used in the cutting step. A respective cutting groove is located between flanking stripes of respective adjacent piezoelectric vibrating devices, so the cutting grooves collectively define the outline profiles of the piezoelectric vibrating devices in the package wafer. The cutting grooves define the outline profiles of the piezoelectric vibrating devices.

The first and second indents are desirably formed on the stripes of the first and second bonding films of the base and lid, respectively.

According to the present invention, multiple piezoelectric devices are manufactured from a package wafer. Each device includes a respective piezoelectric vibrating device exhibiting improved reliability and durability.

### BRIEF DESCRIPTION OF THE DRAWINGS

FIG. 1A is a plan view of the inner surface of a first embodiment of a piezoelectric vibrating device 100 in which a respective tuning-fork type crystal vibrating piece 30 is mounted.

FIG. 1B is an elevational section along the line A-A of the first embodiment shown in FIG. 1A.

FIG. 2 is a plan view of a first embodiment of a package wafer 80W, as viewed from the lid wafer 10W.

FIG. 3A is an enlarged cross-sectional view along the line B-B in FIG. 2. The lid wafer 10W and base wafer 40W are shown vertically aligned with each other.

FIG. 3B is an enlarged cross-sectional view of the region denoted “X” in FIG. 3A.

FIGS. 4A-4F constitute a flow-chart of a method for forming the indents 66, 67.

FIG. 5 is a plan view of a second embodiment of a package wafer 80WA, as viewed from the lid wafer 10WA.

FIG. 5B is an enlarged cross-sectional view along the line C-C in FIG. 5A.

FIG. 6A is a plan view of a third embodiment of a package wafer 80WB, as viewed from the lid wafer 10WB.

FIG. 6B is an enlarged cross-sectional view along the line D-D in FIG. 6A.

FIG. 7A is a plan view of a fourth embodiment of a package wafer 80WC, as viewed from the lid wafer 10WC.

FIG. 7B is an enlarged cross-sectional view along the line E-E in FIG. 7A.

FIG. 8 is a flow-chart of an embodiment of a method for manufacturing piezoelectric devices.

### DETAILED DESCRIPTION

### First Embodiment of Piezoelectric Device

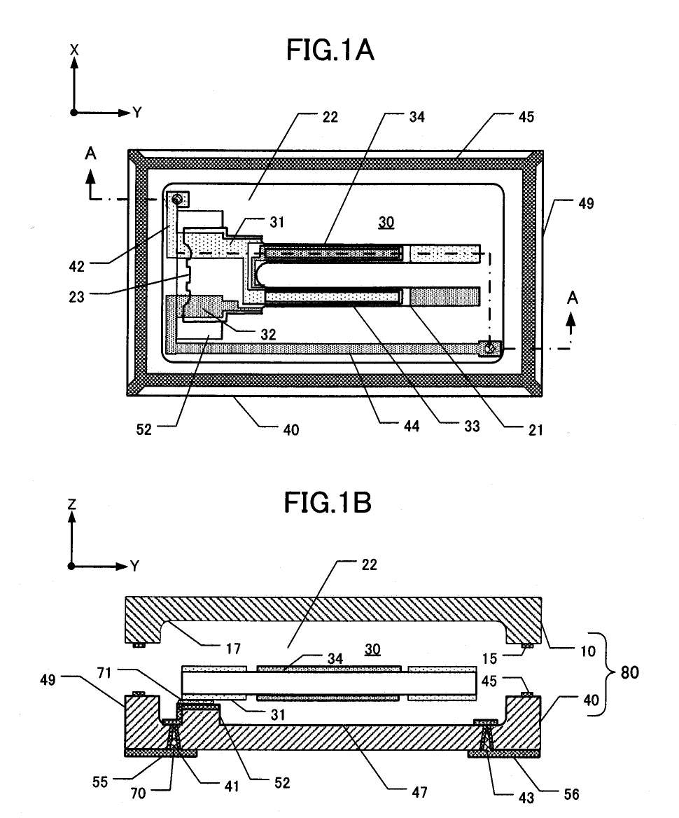

FIGS. 1A and 1B are schematic views of this first embodiment of a piezoelectric vibrating device 100 comprising a tuning-fork type crystal vibrating piece 30. FIG. 1A is a plan view of the inner surface of the device, and FIG. 1B is an elevational section along the line A-A in FIG. 1A. The piezoelectric device 100 comprises a lid 10 and a base 40, which are made of a glass material, for example. The base 40 defines a concavity 47 facing the lid 10. A mount 52 is formed in the concavity 47 and is made of the same glass material as the base 40. The tuning-fork type crystal vibrating piece 30 is mounted to the mount 52.

The base 40 includes a first bonding film 45 on the bonding surface of the base. The bonding surface extends just inboard of the peripheral edge of the base 40 and is the top edge of a frame portion 49 extending around the periphery of the base. The first bonding film 45 essentially comprises linear stripes extending on respective portions of the bonding surface, thereby forming a rectangular figure having four sides. As shown in FIG. 1A, the first bonding film 45 also includes stripes extending diagonally from each corner of the rectangle to respective corners of the base 40.

The lid 10 shown in FIG. 1B includes a second bonding film 15 on the bonding surface of the lid. The bonding surface extends just inboard of the peripheral edge of the lid 10 and is the lower edge of a frame portion extending around the periphery of the lid. The second bonding film 15 essentially comprises linear stripes extending on respective portions of the bonding surface, thereby forming a rectangular figure having four sides. Each of the first and second bonding films 45, 15 is a gold layer having a thickness of 400 Å to 2000 Å.

The base 40 defines a first through-hole 41 and a second through-hole 42 that extend from the inner surface to the outer (under) surface of the base. The concavity 47, the mount 52, the frame portion 49, the first through-hole 41, and the second through-hole 43 are all formed concurrently by etching. A first connecting electrode 42 and a second connecting electrode 44 are formed on the inner surface of the base 40. A first external electrode 55 and a second external electrode 56 are metalized on the outer (under) surface of the base 40. The first and second through-holes 41, 43 each include an interior metal film. The first and second through-holes 41, 43 are sealed by a sealing material 70.

The lid 10 includes a concavity 17 facing the base 40. Surrounding the concavity is a rim including a bonding surface. Applied to the bonding surface are stripes of a second bonding film 15. The stripes form a rectangular pattern with four sides that extend just inboard of the extreme periphery of the lid.

The concavity 17 in the lid 10 and the concavity 47 in the base collectively form a cavity 22. The piezoelectric vibrating device 100 includes the tuning-fork type crystal vibrating piece 30 mounted within the cavity 22 using an electrically conductive adhesive 71.

The tuning-fork type crystal vibrating piece 30 comprises a pair of vibrating arms 21 and a basal portion 23. A first base electrode 31 and a second base electrode 32 are formed on the basal portion 23. Each vibrating arm 21 includes a respective excitation electrode, namely a first excitation electrode 33 and a second excitation electrode 34, respectively. The excitation electrodes are formed on the upper, lower, and side surfaces of the respective vibrating arms 21. The first excitation electrode 33 is connected to a first base electrode 31, and the second excitation electrode 34 is connected to a second base electrode 32.

Each of the first base electrode 31, the second base electrode 32, the first excitation electrode 33, and the second excitation electrode 34 comprises respective metal layers. Example metal layers are 400-2000 Ångstroms (thickness) of gold (Au) layered on 150-700 Ångstroms (thickness) of chromium (Cr). A titanium (Ti) layer can be used instead of the chromium (Cr) layer, and a silver (Ag) layer can be used instead of the gold (Au) layer.

The first base electrode 31 and the second base electrode 32 are connected to a first bonding electrode 42 and a second bonding electrode 44, respectively, using the electrically conductive adhesive 71. The first connecting electrode 42 is connected to the first external electrode 55, on the under-surface of the base 40, via the through-hole 41. Similarly, the second connecting electrode 44 is connected to the second external electrode 56, on the under-surface of the base 40, via the through-hole 43. Thus, the first base electrode 31 is electrically connected to the first external electrode 55, and the second base electrode 32 is electrically connected to the second external electrode 56.

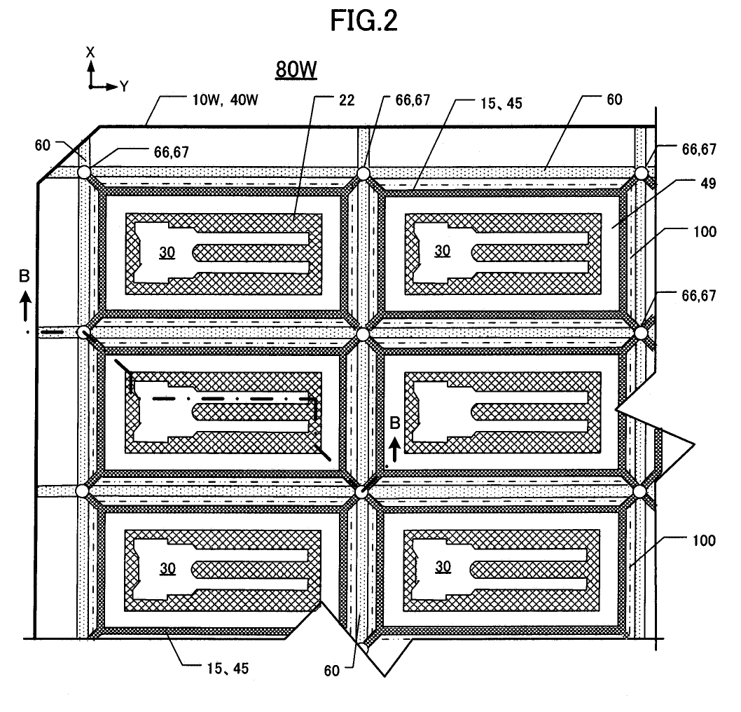

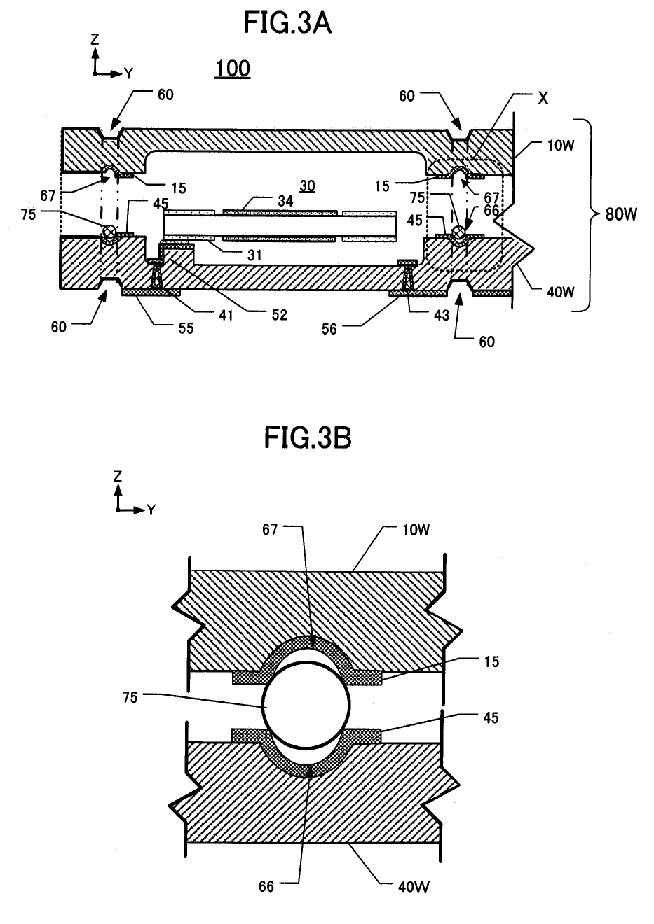

One piezoelectric vibrating device 100 is depicted in FIG. 1 for ease of description. However, during actual manufacture, hundreds or thousands of devices 100 are manufactured simultaneously for higher productivity. That is, multiple bases 40 are formed on a base wafer 40W (see FIGS. 2 and 3), and a respective tuning-fork type crystal vibrating piece 30 is mounted on each base. Similarly, multiple lids 10 are formed on a lid wafer 10W (see FIGS. 2 and 3). On the lid wafer 10W, the multiple lids 10 are located so as to be alignable with respective bases 40 on the base wafer 40W.

After aligning the base wafer 40W and lid wafer 10W in this way, the wafers are bonded together by bonding together all the lids 10 with their respective bases 40, thereby forming a package wafer 80W having all the attached piezoelectric devices 100. Finally, the package wafer 80W is diced to separate the individual piezoelectric devices 100 from one another.

FIG. 2 is a plan view of the package wafer 80W, as viewed from the lid wafer 10W. For comprehension, the lid wafer 10W is depicted as if it were transparent, and the figure mainly shows the tuning-fork type crystal vibrating piece 30 mounted on the base 40. An area (X-Y plane) corresponding to one piezoelectric vibrating device 100 is delineated with a virtual line (two-dotted chain line) on the package wafer 80W. Also, the cavities 22 are depicted as meshed zones to distinguish the tuning-fork type crystal vibrating piece 30 from other structure.

As shown in FIG. 2, cutting grooves 60 are formed on the lid wafer 10W. Corresponding cutting grooves 60, formed on the under-surface of the base wafer 40W (see FIG. 3A), are aligned (in the X-Y plane) with the cutting grooves 60 on the lid wafer 10W. The cutting grooves 60 are situated between adjacent virtual lines (two-dotted chain lines). The package wafer 80W is affixed to a dicing film (not shown) and is cut along the cutting grooves 60 using a dicing saw. The cutting grooves 60 prevent cracks from forming on the piezoelectric devices 100 whenever the package wafer 80W is being cut by the dicing saw. During cutting the dicing saw moves linearly between the walls of the cutting grooves 60 of the lid wafer 10W and base wafer 40W. The depth of each cutting groove 60 is in the range of 20 to 70 μm. By providing the lid wafer 10W and base wafer 40W with cutting grooves 60, the cutting load for the dicing saw is reduced, which improves work efficiency. The cutting grooves also prevent chipping or cracking of the package wafer 80W during dicing.

The stripes of the second bonding film 15 formed on the lid wafer 10W and the stripes of the first bonding film 45 formed on the base wafer 40W are situated so as to be in registration with each other in the package wafer 80W. Additional stripes of the first and second bonding films 45, 15 extend from respective corners of each rectangle toward the respective cutting grooves 60. The additional stripes extend from respective corners of the rectangles toward the X-axis at angles of + or −45°. The additional stripes cross each other at loci identical to loci (on the X-Y plane) at which respective cutting grooves 60 cross each other. First and second indents 66, 67 are situated at loci at which stripes of the bonding films 45, 15 cross each other.

FIG. 3A is an enlarged elevational view of a portion of the package wafer 80W along the line B-B in FIG. 2. The lid wafer 10W and base wafer 40W are shown aligned with each other. FIG. 3B is an enlarged cross-sectional view of the region denoted “X” in FIG. 3A. As shown in FIG. 3A, the first indents 66 are formed on a major surface of the base 40 (i.e., the inner major surface) that is opposite the major surface on which the cutting grooves 60 are formed. Similarly, the second indents 67 are formed on a major surface of the lid (i.e., the inner major surface) that is opposite the major surface on which the cutting grooves 60 are formed.

As shown in FIG. 3B, each of the first and second indents 66, 67 is formed as a hemispherical concavity. Respective stripes of the first bonding film 45 extend onto each first indent 66, and respective stripes of the second bonding film 15 extend onto each second indent 67. A respective bonding ball 75 is placed on each of the first indents 66 on the base wafer 40W. Thus, the bonding ball 75 becomes sandwiched between the respective first indent 66 and second indent 67. The bonding balls 75 serve as placement guides for aligning and placing the lid wafer 10W on the base wafer 40W, thereby avoiding misalignment of the base wafer 40W and lid wafer 10W. The bonding ball 75 is a eutectic metal ball comprising, for example, a gold-silicon alloy (Au_{3.15}Si) or a gold-germanium (Au₁₂Ge) alloy.

The base wafer 40W and lid wafer 10W are bonded together by material of the bonding balls 75. To such end, there desirably is a space (see FIG. 3B) between the first bonding film 45 and the second bonding film 15 before the bonding balls 75 are melted. This space allows the interior cavities 22 of the package wafer 80W to be evacuated to a desired vacuum level whenever the package wafer 80W is kept/heated in a reflow furnace under vacuum conditions. This space also allows the cavities 22 to be filled with an inert gas if the reflow furnace operates under an inert gas environment.

As the bonding balls 75 melt, the resulting eutectic melt flows along the respective stripes of the first and second bonding films 45, 15, thereby “wetting” the surfaces of the stripes by capillary action. Upon completion of wetting, the melt is allowed to cool sufficiently to complete bonding. As noted above, the bonding films 45, 15 can be bonded together while the inside of the cavities 22 is evacuated or filled with an inert gas.

Returning to FIG. 2, the first indents 66 are formed just outboard of areas delineated by the two-dotted chain line (these lines delineate the extreme peripheries of adjacent piezoelectric vibrating devices 100). As a result, stripes of the first bonding film 45 and second bonding film 15 forming the rectangular patterns of such stripes are formed just inboard of the extreme peripheries. In these inboard areas there are no indents. The absence of indents in these stripes facilitates capillary flow of the eutectic melts from the molten bonding balls 75. As a result, bonding of the lid wafer 10W to the base wafer 40W can be done securely.

The first indents 66 and second indents 67 are aligned with the cutting grooves 60 in the Z-direction, which may allow chips of wafer material generated by contact with a dicing blade to attach to the blade. To minimize possible adverse effects of this, regions of the stripes of first bonding film 45 and second bonding film 15 near the first indent 66 and second indent 67 are preferably as thin as possible.

### Forming the First and Second Indents

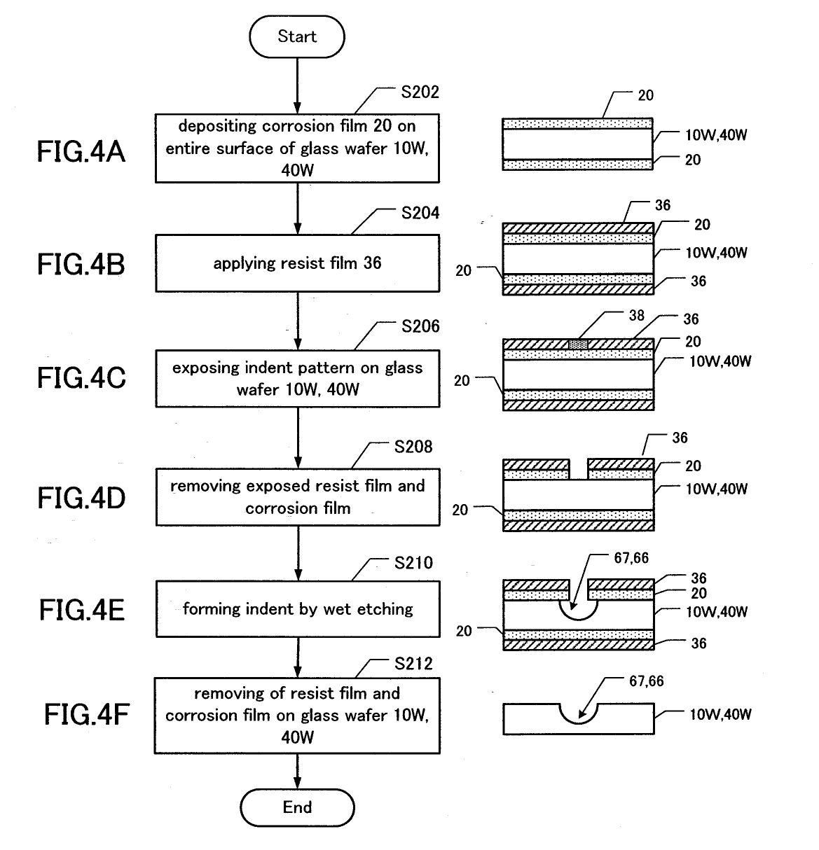

FIGS. 4A-4F constitute a flow-chart of an embodiment of a method for forming the indents 66, 67. Cross-sections of the wafer (made of a glass material), showing respective results of each step are provided along on the right side of the flow-chart. Although the indents 66, 67 are formed concurrently with formation of the concavities 17, 47 on the lid wafer 10W and base wafer 40W, respectively, only formation of an indent is shown and described.

In FIG. 4A (step S202) a corrosion-resistant film 20, such as gold (Au) or silver (Ag), is formed on the major surfaces of the lid wafer 10W and base wafer 40W by sputtering or vacuum-deposition. Since the lid wafer 10W and base wafer 40W are made of glass, gold (Au) or silver (Ag) can be formed directly on the respective surfaces of the wafers. FIG. 4A includes a cross-section of the lid wafer 10W or base wafer 40W upon completion of this step.

In FIG. 4B (step S204) a photoresist film 36 is evenly applied by spin-coating on the major surfaces of the lid wafer 10W and base wafer 40W on which the corrosion-resistant film 20 was formed. An exemplary photoresist film 36 is a positive photoresist made of novolak. FIG. 4B includes a cross-section of the lid wafer 10W or base wafer 40W upon completion of this step.

Next, in FIG. 4C (step S206), using a lithographic exposure device (not shown), an indent pattern is exposed onto the photoresist 36 on the lid wafer 10W and base wafer 40W. Each indent 66, 67 is a hemisphere having a diameter in the range of 150 μm to 200 μm, while the diameter of each hole in the indent pattern is 50 μm. FIG. 4C includes a cross-section of the lid wafer 10W or base wafer 40W upon completion of this step.

In FIG. 4D (step S208) the photoresist films 36 on the lid wafer 10W and base wafer 40W are developed, followed by removal of the exposed photoresist film 38. Respective regions of the gold layer revealed by removal of exposed resist 36 are etched using an aqueous solution of iodine and potassium iodide. The concentrations of etching solutes, temperature, and etching time are controlled to avoid over-etch. Thus, revealed portions of the corrosion-resistant film 20 are removed. FIG. 4D includes a cross-section of the lid wafer 10W or base wafer 40W in which holes for the indents have been formed.

In FIG. 4E (step S210) portions of the lid wafer 10W and base wafer 40W revealed by removal of regions of corrosion-resistant film 20 are wet-etched using a hydrofluoric acid solution to form the profile outlines of the indents 66 and 67. The duration of wet-etching is a function of concentration, type, and temperature of the hydrofluoric acid solution. The glass wafer is etched radially from the small hole so that the indent assumes a hemispherical shape. FIG. 4E includes a cross-section of the lid wafer 10W or base wafer 40W after etching, depicting the hemispherical indents 66, 67. The hemispherical shapes are covered by the corrosion-resistant film 20 and the photoresist film 36. FIG. 4E includes a cross-section of an indent 66, 67 having a greater diameter than the diameter of the hole in the indent pattern.

In FIG. 4F (step S212) the hemispherical indents 66 and 67 are formed by removing the remaining photoresist film 36 and the corrosion-resistant film 20. For comprehension, in the figure the indent 66, 67 is depicted enlarged. At least one stripe of bonding film 45, 15 extends onto the indent 66, 67 in the course of forming the stripe. FIG. 4F includes a cross-section of an indent 66, 67 thus formed.

### Second Embodiment of Piezoelectric Device

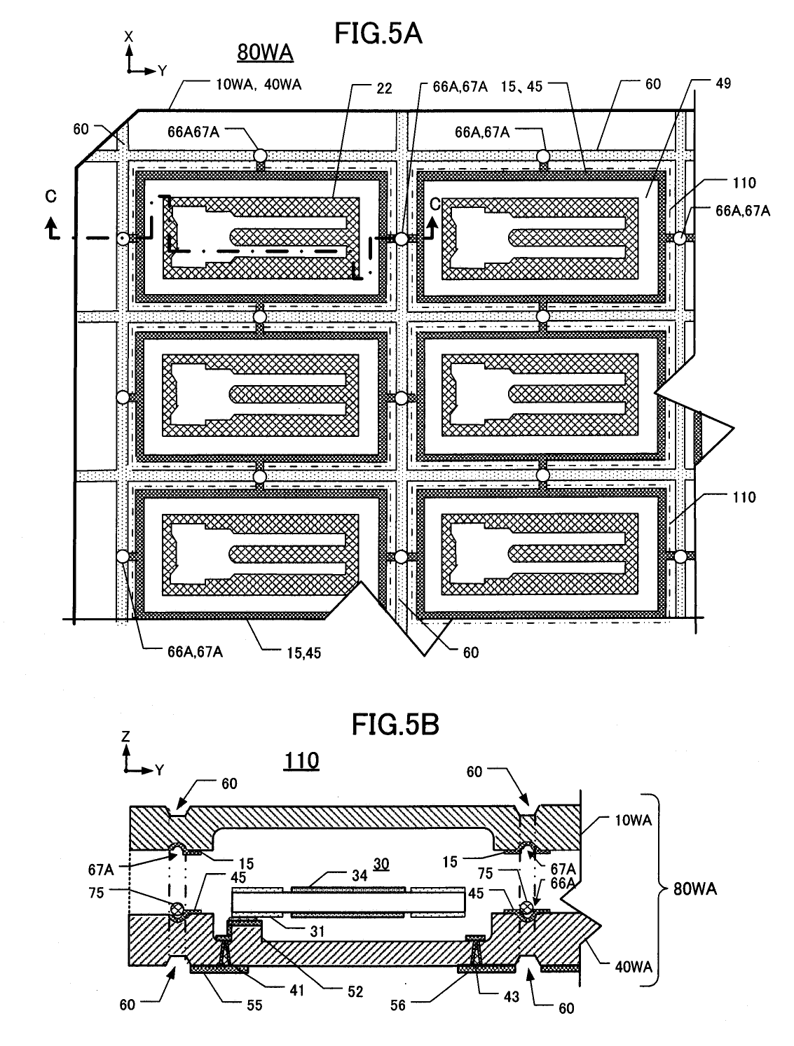

FIG. 5A is a plan view of a package wafer 80WA, as viewed from above the lid wafer 10WA, used for producing multiple piezoelectric devices 110 according to the second embodiment. The lid wafer 10WA is depicted as if it were transparent, and the figure mainly shows tuning-fork type crystal vibrating pieced 30 mounted on respective bases 40A. For comprehension, respective areas (in the X-Y plane) corresponding to single respective piezoelectric vibrating devices 110 are delineated using a virtual line (two-dotted chain line) on the package wafer 80WA. Voids 22 are depicted as meshed zones to distinguish the tuning-fork type crystal vibrating piece 30 in each device 110. FIG. 5B is an enlarged elevational section along the line C-C in FIG. 5A. For comprehension, FIG. 5B shows the constituent wafers 10WA and 40 WA separated from each other in the Z-direction.

The stripes of the first bonding film 45 and second bonding film 15 in this device 110 have a different pattern than in the first embodiment. Also the positions of the first indents 66A and the second indents 67A of this device 110 are different from corresponding positions of the indents in the first embodiment 100. Only the differences from the first embodiment 100 are described below.

The package wafer 80WA comprises a lid wafer 10WA defining multiple lids 10A and a base wafer 40WA defining multiple corresponding bases 40A. The tuning-fork type crystal vibrating piece 30 is mounted on a mount 52, which is part of the base 40A.

As shown in FIGS. 5A and 5B, the stripes of the second bonding film 15 on the lid wafer 10WA face the base wafer 40WA. The base wafer 40WA includes corresponding stripes of the first bonding film 45. The stripes of both bonding films 45, 15 not only form a rectangular pattern in each device 110, but also have short extensions extending from the mid-point of each stripe outward toward the respective cutting groove 60. Thus, with respect to each stripe of the first bonding film 45 on adjacent bases 40A and each stripe of the second bonding film 15 on adjacent lids, a respective short perpendicular stripe crosses the adjacent cutting groove 60.

As shown in FIG. 5B, first indents 66A are formed on the inner major surface of the base wafer 40WA, which is opposite the outer major surface on which the cutting grooves 60 are formed. Second indents 67A are formed on the inner major surface of the second lid 10A opposite the outer major surface on which the cutting grooves 60 are formed. In this embodiment the first and second indents 66A and 67A are not formed on the intersections of cutting grooves 60 extending in the X-axis direction and cutting grooves 60 extending in the Y-axis direction (compare to first embodiment). Nevertheless, individual first and second indents 66A and 67A have a hemispherical shape. A bonding ball 75 is placed in each first indent 66A. As shown in FIG. 5A, the first indents 66A are formed just outboard of the area corresponding to the piezoelectric vibrating device 110 (i.e., outside the two-dotted chain line). As a result, the stripes of the first bonding film 45 and second bonding film 15 located just inboard of the periphery of each piezoelectric vibrating device 110 (two-dotted chain line) are planar and lack any indents.

### Third Embodiment of Piezoelectric Vibrating Device

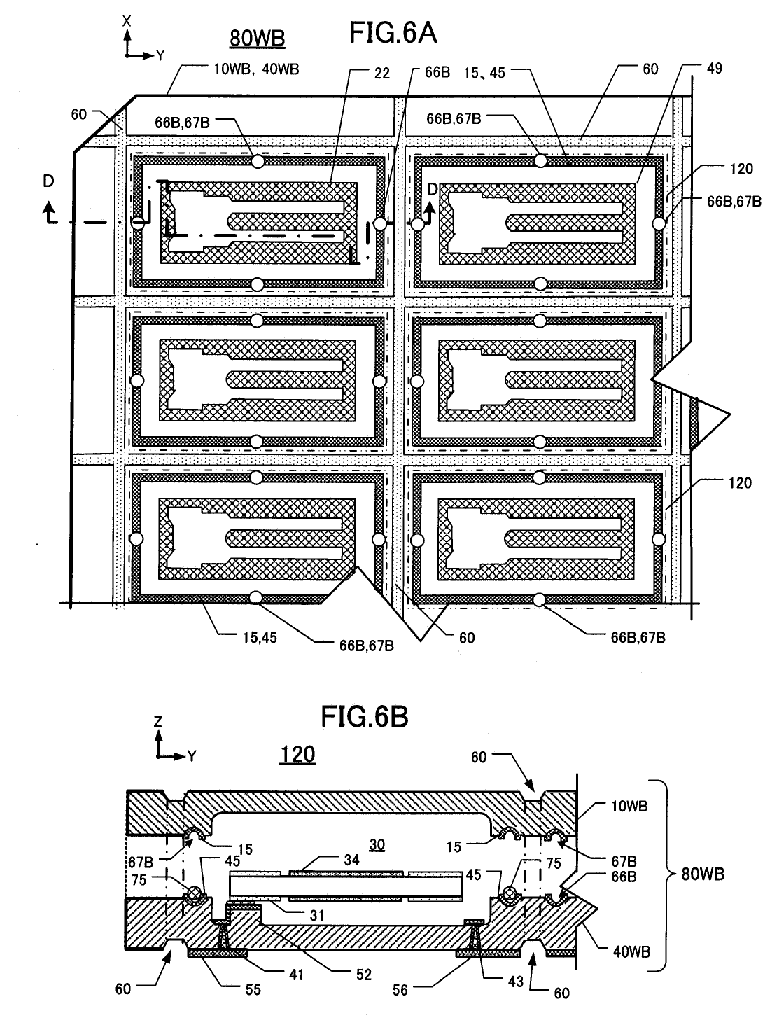

FIG. 6A is a plan view of a package wafer 80WB of this embodiment, as viewed from above the lid wafer 10WB. FIG. 6B is an enlarged elevational view along the line D-D of FIG. 6A. The lid wafer 10WB is depicted as if it were transparent, and the figure mainly shows the tuning-fork type crystal vibrating piece 30 mounted on the base 40B. For comprehension, respective areas (in the X-Y plane) of individual piezoelectric vibrating devices 120 are delineated using a virtual line (two-dotted chain line) on the package wafer 80WB. Voids are shown as meshed zones to distinguish the tuning-fork type crystal vibrating piece 30.

The piezoelectric vibrating device 120 of this embodiment differs from the piezoelectric vibrating device 100 of the first embodiment in that each first indent 66B and second indent 67B of the third embodiment is located at substantially the mid-length of the respective stripe of bonding film. Further description below will focus only on the differences of this embodiment 120 from the first embodiment 100 of a piezoelectric vibrating device. Similar components in each embodiment have the same reference numerals.

In FIG. 6A the stripes of second bonding film 15 are formed on the lid wafer 10WB so as to be aligned (in the X-Y plane) with respective stripes of the first bonding film 45 on the base wafer 40WB. The stripes of the second bonding film 15 and first bonding film 45 are located inboard of the outline profile of each piezoelectric vibrating device 120 so as not to touch the cutting grooves 60.

The first indents 66B are located at mid-length of the respective stripes of the first bonding film 45. Similarly, the second indents 67B are located at mid-length of the respective stripes of the second bonding film 15. Each of the first indents 66A and second indents 67A has a hemispherical shape. Since the distance between adjacent (in the Z-direction) stripes of the first and second indents 66B, 67B is substantially constant, as the bonding ball 75 melts, the melt flows along and between the adjacent surfaces of the bonding films 45, 15 by capillary action, which “wets” the surfaces of the bonding films 45, 15 with the melt.

As shown in FIG. 6B, the first indents 66B and second indents 67B of this embodiment are not situated on the cutting grooves 60. As a result, when the package wafer 80WB is being cut using a dicing blade, chipped metal does not clog the blade.

### Fourth Embodiment of a Piezoelectric Vibrating Device

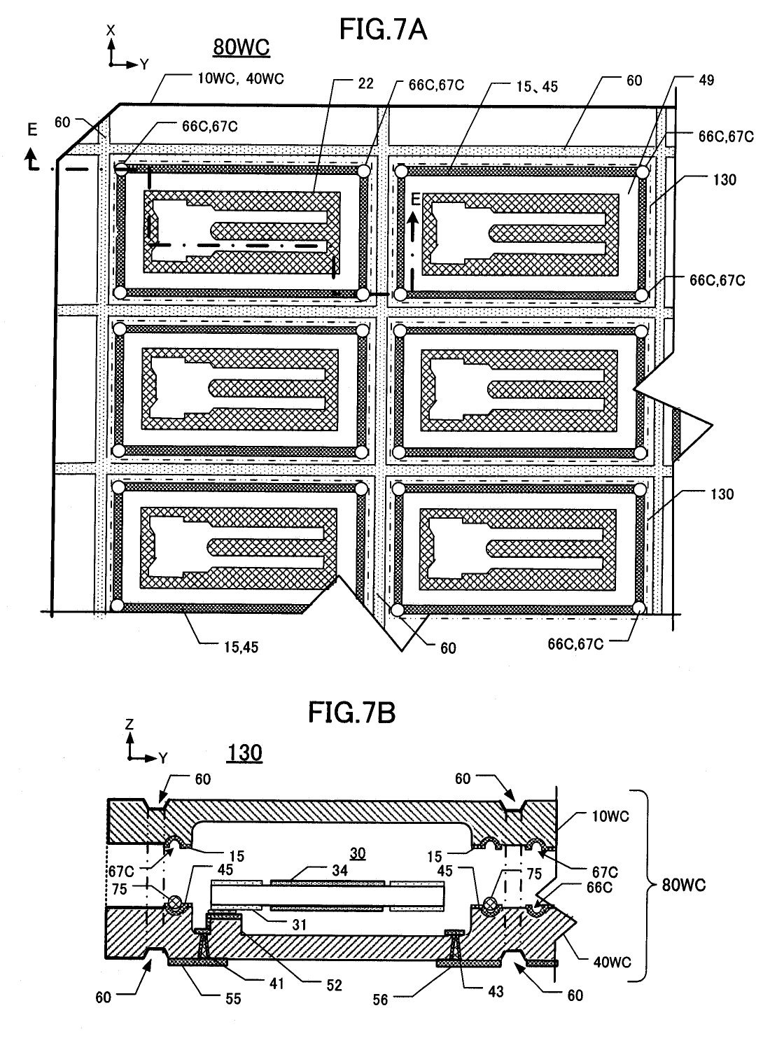

FIG. 7A is a plan view of the package wafer 80WC of this embodiment, as viewed from above the lid wafer 10WC. FIG. 7B is an enlarged elevational section along the line E-E in FIG. 7A. The lid wafer 10WC is shown as if it were transparent, and the figure mainly shows the tuning-fork type crystal vibrating piece 30 mounted on the base 40C. For comprehension, areas (in the X-Y plane) corresponding to respective piezoelectric vibrating devices 130 are delineated with a virtual line (two-dotted chain line) on the package wafer 80WC. Voids are depicted as meshed zones to distinguish the tuning-fork type crystal vibrating piece 30.

In this embodiment stripes of the bonding films 45, 15 form rectangular patterns. A first indent 66C is formed at each corner of the rectangle formed by stripes of the first bonding film 45, and a second indent 67C is formed at each corner of the rectangle formed by stripes of the second bonding film 15. This arrangement of stripes and indents distinguishes this embodiment from the third embodiment. Below, only differences from the third embodiment are described, wherein similar components have similar respective reference numerals.

As shown in FIGS. 7A and 7B, the stripes of the second bonding film 15 on the lid wafer 10WC face corresponding stripes of the first bonding film 45 on the base wafer 40WC, with a second indent 67C at each corner of the rectangular stripe pattern. The base wafer 40WC includes stripes of the first bonding film 45, with a first indent 66C at each corner of the rectangular stripe pattern. The first indents 66C and second indents 67C are located on the respective “bonding surfaces” of the lid wafer 10WC and base wafer 40WC. The first indents 66C and second indents 67C each have a hemispherical shape, and a respective bonding ball 75 is placed on each pair of opposing indents.

### Exemplary Method for Manufacturing Piezoelectric Devices

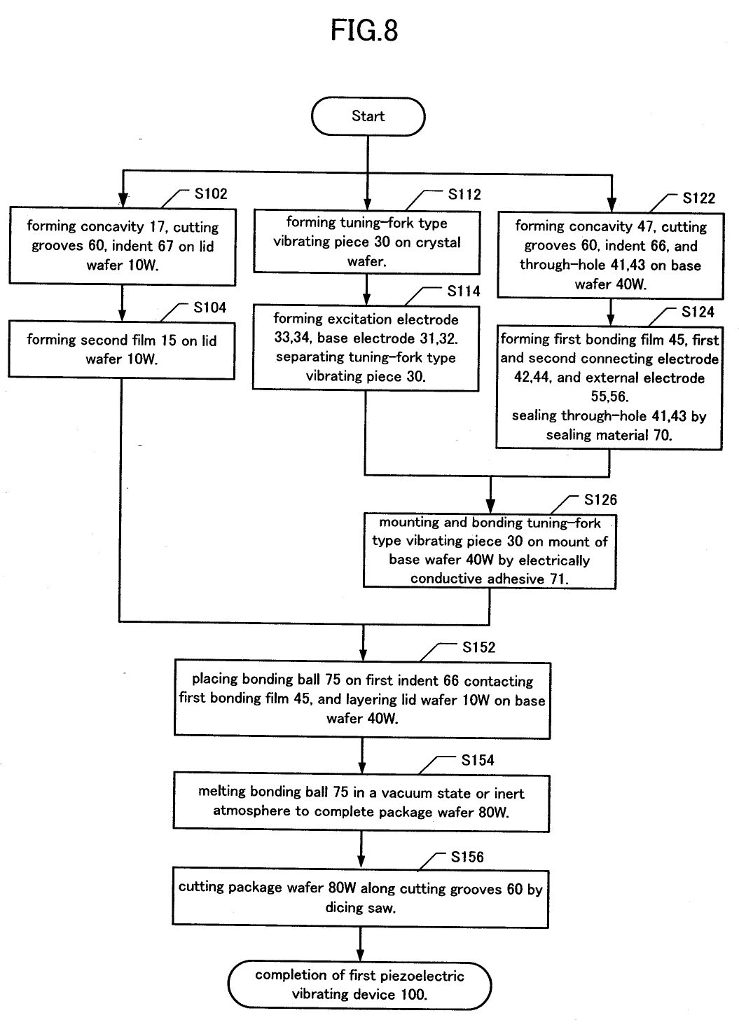

An embodiment of a method for manufacturing a piezoelectric device 100 according to the first embodiment is described below. A flow-chart of the method is shown in FIG. 8.

Steps S102 and S104 are applied to the lid wafer 10W, steps S112 and S114 are applied to the crystal wafer used for forming vibrating pieces, and steps S122 and S124 are applied to the base wafer 40W. Step S152 and subsequent steps are applied to package wafers.

In step S102 multiple lids 10 (including the concavity 17, cutting grooves 60, and second indents 67) are formed on the lid wafer 10W, made of glass. Hundreds or thousands of such lids 10 are formed on the lid wafer 10W, depending upon the size of the lid wafer and the size of each lid.

In step S112 multiple tuning-fork type crystal vibrating pieces 30 are formed on a crystal wafer by wet-etching. Hundreds or thousands of tuning-fork type crystal vibrating pieces 30 are formed on the crystal wafer, depending upon the size of the crystal wafer and the size of each vibrating piece.

In step S114 respective excitation electrodes 33, 34 and base electrodes 31, 32 are formed on the each crystal vibrating piece 30 formed on the crystal wafer. Each thus-formed tuning-type crystal vibrating piece 30 is cut and separated from the crystal wafer.

In step S122, multiple bases 40 (having the concavity 47, cutting grooves 60, first indents 66, and first and second through-holes 41, 43) are formed on the base wafer 40W, made of glass. Hundreds or thousands of bases 40 are formed on the base wafer 40W, depending upon the size of the base wafer and the size of each base.

In step S124 respective first and second connecting electrodes 42, 44 and first and second external electrodes 55, 56 are formed on each base wafer 40W.

The first and second through-holes 41, 42, previously formed on the base wafer 40W, are sealed by melting a sealing material 70. The sealing material 70 is a ball of eutectic metal such as gold-silicon (Au_{3.15}Si) alloy or gold-germanium (Au₁₂Ge) alloy.

In step S126 a respective tuning-fork type crystal vibrating piece 30 is mounted, using electrically conductive adhesive 71, on a respective mount 52 in the cavity 22 of each base on the base wafer 40W. First, a unit of the electrically conductive adhesive 71 is applied from a dispenser to a site on the mount 52, followed by placement of the respective tuning-fork type crystal vibrating piece 30, held by a holding device (not shown), on the unit of electrically conductive adhesive. The tuning-fork type crystal vibrating pieces 30 are thus mounted one at a time to the respective mounts 52 in the cavities 22 in the base wafer 40W. After mounting all the tuning-fork type crystal vibrating pieces 30 on the mounts 52, the electrically conductive adhesive 71 is cured to solidify it. Then, each tuning-fork type crystal vibrating piece 30 is connected to the respective first connecting electrode 42 and second connecting electrode 44 on the base wafer 40W, both mechanically and electrically. For example, each unit of adhesive 71 is obtained from a paste of silicon-based electrically conductive adhesive or epoxy-based electrically conductive adhesive.

In step S152 a respective bonding ball 75 is placed on each first indent 66 on the stripes of the first bonding film 45 of the base wafer 40W. The first indents 66 each have a hemispherical shape to accommodate a respective bonding ball 75. As the lid wafer 10W is lowered onto the base wafer 40W, the second indents 67 of the lid wafer 10W are placed atop respective bonding balls 75. Thus, the bonding balls 75 serve as alignment guides for achieving alignment of the lid wafer 10W with the base wafer 40W. The second indents 67 also have a hemispherical shape to facilitate fitting to the respective bonding balls 75, thereby ensuring that the lid wafer 10W does not move relative to the base wafer 40W. This stability of the lid wafer 10W relative to the base wafer 40W is maintained through placement of the stacked wafers in a reflow furnace (not shown).

In the reflow furnace, the bonding balls are melted (step S154). A portion of the melt flows over the bonding surface of the first base wafer 40W, as facilitated by capillary action of the respective stripes. Melting of the bonding balls 75 can be conducted, in the furnace, in either a vacuum or inert-gas environment. Thus, the void 22 is evacuated or filled with an inert gas. As the bonding balls 75 melt, the resulting melt flows and spreads to the stripes of the first and second bonding films 45, 15. After completion of melt flow, the temperature of the reflow furnace is reduced to a predetermined temperature. This bonding together the first and second bonding films 45, 15 forms the package wafer 80W.

In step S156, the package wafer 80W is affixed to a dicing film (not shown) and cut along the cutting grooves 60 using a dicing saw. By providing appropriate space between the dicing saw and the cutting grooves 60, the dicing saw can cut the package wafer without touching the dicing sheet or the adhesive. As a result, burrs or chips are not produced during dicing.

Upon completing the foregoing steps, fabrication of the piezoelectric devices 100 is completed. Since the interior of each piezoelectric device 100 is in a vacuum state or filled with an inert gas, each device produces stable oscillations.

By forming each package using the respective bonding films and indents formed on the lid and base, hermetic sealing of each piezoelectric device is ensured.

In the foregoing method embodiment, the lid and base are made of glass. In other embodiments other materials may be used such as a crystal material (e.g., quartz crystal). The reason for allowing this substitution is as follows. One of the indicators of hardness of an industrial material is the “Knoop hardness.” A higher Knoop hardness number indicates greater hardness, and a lower number indicates greater softness. The Knoop hardness number of borosilicate glass (commonly used for making lids and bases) is 590 kg/mm², and the Knoop hardness number of quartz crystal is 710 to 790 kg/mm². Thus, making the lids and bases of crystal instead of glass produces vibrating devices having a higher degree of hardness. If the lids and bases are made of glass, the thickness of glass would have to be correspondingly thicker to meet a designated degree of hardness and strength. But, when fabricated of crystal, these components can be made with a thinner profile while achieving the same strength and hardness. I.e., in fabricating piezoelectric devices in which the lids and bases are made of crystal instead of glass, devices having the same strength and hardness as obtained when they are made of glass can be made that are more miniaturized and thinner than if they were made of glass.

In the embodiments described above, the vibrating devices included respective tuning-fork type crystal vibrating pieces. In alternative embodiments, AT-cut crystal panels can be used instead that exhibit thickness shear vibrations. In addition, in various alternative embodiments, other combinations of bonding surfaces and/or shapes of bonding materials can be used.

What is claimed is:

1. A method for manufacturing piezoelectric devices, comprising:
preparing a base wafer defining multiple bases, each base having respective sides and a respective periphery, each base including a respective stripe of a first bonding film extending inboard of each edge around the periphery, each base also including at least one first indent formed adjacent each respective edge and contacting the respective stripe of the first bonding film;
preparing a lid wafer defining multiple lids, each lid having respective sides and a respective periphery, each base including a respective stripe of a second bonding film extending inboard of each edge around the periphery, each lid also including at least one second indent formed adjacent each respective edge and contacting the respective stripe of the second bonding film;
applying a respective unit of bonding material onto each of the first indents or each of the second indents;
aligning the lid wafer with the base wafer such that the wafers are separated from each other by the units of bonding material situated between respective opposing first and second indents;
melting the bonding material and flowing the melted bonding material from the indents along the stripes of the first and second bonding films; and
solidifying the bonding material to bond the base wafer and lid wafer together to form a package wafer.

2. The method of claim 1, wherein the first indents and the second indents each have a hemispherical shape.

3. The method of claim 2, wherein the indents are formed by etching a pattern made using a mask defining respective holes.

4. The method of claim 3, wherein melting and solidifying are performed in a vacuum state or in an inert gas environment.

5. The method of claim 3, further comprising, after melting and solidifying, cutting the package wafer to separate individual piezoelectric vibrating devices from one another.

6. The method of claim 5, wherein the respective stripes of the first and second bonding films are formed in respective regions that are not cut during cutting the package wafer.

7. The method of claim 5, wherein:
preparing the base wafer further comprises forming a respective cutting groove between each adjacent base to guide cutting of the package wafer to form the individual piezoelectric vibrating pieces; and
preparing the lid wafer further comprises forming a respective cutting groove between each adjacent lid to guide cutting of the package wafer to form the individual piezoelectric vibrating pieces.

8. The method of claim 2, wherein melting and solidifying are performed in a vacuum state or in an inert gas environment.

9. The method of claim 8, further comprising, after melting and solidifying, cutting the package wafer to separate individual piezoelectric vibrating devices from one another.

10. The method of claim 2, further comprising, after melting and solidifying, cutting the package wafer to separate individual piezoelectric vibrating devices from one another.

11. The method of claim 10, wherein the respective stripes of the first and second bonding films are formed in respective regions that are not cut during cutting the package wafer.

12. The method of claim 10, wherein:
preparing the base wafer further comprises forming a respective cutting groove between each adjacent base to guide cutting of the package wafer to form the individual piezoelectric vibrating pieces; and
preparing the lid wafer further comprises forming a respective cutting groove between each adjacent lid to guide cutting of the package wafer to form the individual piezoelectric vibrating pieces.

13. The method of claim 1, wherein melting and solidifying are performed in a vacuum state or in an inert gas environment.

14. The method of claim 13, further comprising, after melting and solidifying, cutting the package wafer to separate individual piezoelectric vibrating devices from one another.

15. The method of claim 14, wherein:
preparing the base wafer further comprises forming a respective cutting groove between each adjacent base to guide cutting of the package wafer to form the individual piezoelectric vibrating pieces; and
preparing the lid wafer further comprises forming a respective cutting groove between each adjacent lid to guide cutting of the package wafer to form the individual piezoelectric vibrating pieces.

16. The method of claim 1, further comprising, after melting and solidifying, cutting the package wafer to separate individual piezoelectric vibrating devices from one another.

17. The method of claim 16, wherein the respective stripes of the first and second bonding films are formed in respective regions that are not cut during cutting the package wafer.

18. The method of claim 16, wherein:
preparing the base wafer further comprises forming a respective cutting groove between each adjacent base to guide cutting of the package wafer to form the individual piezoelectric vibrating pieces; and
preparing the lid wafer further comprises forming a respective cutting groove between each adjacent lid to guide cutting of the package wafer to form the individual piezoelectric vibrating pieces.

19. A piezoelectric vibrating device, manufactured according to claim 1, wherein the first indents or second indents are formed on respective stripes of the first bonding film or the second bonding film, respectively.

20. A piezoelectric vibrating device manufactured according to claim 2, wherein the first indents or second indents are formed on respective stripes of the first bonding film or the second bonding film, respectively.
